(19) United States
(12) Patent Application Publication
(10) Pub. No.: US 2026/0271635 A1
(43) Pub. Date: Sep. 10, 2026

(54) ATOMIC LAYER DEPOSITION WITH CARBON INHIBITION PROFILE TUNING

(71) Applicant: Applied Materials, Inc., Santa Clara, CA (US)

(72) Inventors: Sukrant Dhawan, Santa Clara, CA (US); Susmit Singha Roy, Campbell, CA (US); Supriya Ghosh, San Jose, CA (US); Rui Wang, Sunnyvale, CA (US); Akhil Singhal, Portland, OR (US); Abdul Aziz Khaja, San Jose, CA (US); Lihua Wu, Fremont, NY (US)

(73) Assignee: Applied Materials, Inc., Santa Clara, CA (US)

(21) Appl. No.: 19/072,156

(22) Filed: Mar. 6, 2025

(51) Int. Cl. H01L 21/02; C23C 16/02; C23C 16/44; C23C 16/455

(52) U.S. Cl. CPC H10P 14/6339; C23C 16/0272; C23C 16/4408; C23C 16/45538; H10P 14/6336; H10P 14/6681

(57) ABSTRACT

Exemplary methods of semiconductor processing may include i) performing a carbon inhibition operation on a substrate disposed within a processing region of a semiconductor processing chamber. A layer of material may be disposed on the substrate. The layer of material may define one or more features characterized by an aspect ratio of greater than or about 30:1. The methods may include ii) performing a silicon-containing atomic layer deposition (ALD) process. The silicon-containing ALD may deposit a silicon-containing material in the one or more features. The methods may include iii) repeating operations i and ii for a plurality of cycles.

### TECHNICAL FIELD

The present technology relates to methods and components for semiconductor processing. More specifically, the present technology relates to systems and methods for depositing silicon-containing materials with reduced seam and/or void presence.

### BACKGROUND

Integrated circuits are made possible by processes which produce intricately patterned material layers on substrate surfaces. Producing patterned material on a substrate requires controlled methods of formation and removal of exposed material. As device sizes continue to shrink, features within the integrated circuits may get smaller and aspect ratios of structures may grow, and maintaining dimensions of these structures during processing operations may be challenged. Some processing may result in seams or voids in the materials that may result in unwanted and undesirable effects in further processing. Developing materials that can control seam or void formation may become more difficult.

Thus, there is a need for improved systems and methods that can be used to produce high quality devices and structures. These and other needs are addressed by the present technology.

### SUMMARY

Exemplary methods of semiconductor processing may include i) performing a carbon inhibition operation on a substrate disposed within a processing region of a semiconductor processing chamber. A layer of material may be disposed on the substrate. The layer of material may define one or more features characterized by an aspect ratio of greater than or about 30:1. The methods may include ii) performing a silicon-containing atomic layer deposition (ALD) process. The silicon-containing ALD may deposit a silicon-containing material in the one or more features. The methods may include iii) repeating operations i and ii for a plurality of cycles.

In embodiments, the one or more features may be characterized by a width of less than or about 250 nm. The one or more features may be characterized by a depth of greater than or about 1 μm. The one or more features may be characterized by an aspect ratio of greater than or about 50:1. The inhibition operation may include contacting the substrate with a carbon-containing precursor. The carbon-containing precursor may be or include acetylene (C₂H₂). The methods may include forming plasma effluents of the carbon-containing precursor. The inhibition operation may reduce deposition of silicon-containing material at an upper portion of the one or more features. The silicon-containing ALD may include: ii-a) depositing the silicon-containing material on the substrate; ii-b) purging the processing region after operation ii-a; ii-c) exposing the silicon-containing material to an oxygen-containing precursor to convert the silicon-containing material to a silicon-and-oxygen-containing material; and ii-d) purging the processing region after operation ii-c. The silicon-containing ALD may be plasma-enhanced. The inhibition operation may prevent closing of the one or more features with the silicon-containing material. The silicon-containing material may be seam-free and void-free. Subsequent to one or more cycles, a pressure within the processing region may be reduced.

Some embodiments of the present technology may encompass semiconductor processing methods. The methods may include providing a carbon-containing precursor to a processing region of a semiconductor processing chamber. A substrate may be housed within the processing region. A layer of material may be disposed on the substrate. The layer of material may define one or more features characterized by an aspect ratio of greater than or about 30:1. The methods may include forming plasma effluents of the carbon-containing precursor. The methods may include contacting the substrate with the carbon-containing precursor. The contacting may form a carbon-containing material on an upper portion of the one or more features. The methods may include performing a silicon-and-oxygen-containing atomic layer deposition (ALD) process. The silicon-and-oxygen-containing ALD may deposit a silicon-and-oxygen-containing material in the one or more features.

In embodiments, the carbon-containing precursor may be or include acetylene (C₂H₂). The methods may include repeating providing the carbon-containing precursor to the processing region, contacting the substrate with the carbon-containing precursor, and performing a silicon-containing ALD for a plurality of cycles to iteratively fill the one or more features. Subsequent to one or more cycles, a plasma power may be reduced.

Some embodiments of the present technology may encompass semiconductor processing methods. The methods may include providing a carbon-containing precursor and a nitrogen-containing precursor to a processing region of a semiconductor processing chamber. A substrate may be housed within the processing region. A layer of material may be disposed on the substrate. The layer of material may define one or more features characterized by an aspect ratio of greater than or about 30:1. The methods may include forming plasma effluents of the carbon-containing precursor and the nitrogen-containing precursor. The methods may include contacting the substrate with the plasma effluents of the nitrogen-containing precursor and the nitrogen-containing precursor. The contacting may form a carbon-containing material on an upper portion of the one or more features. The methods may include performing a silicon-and-oxygen-containing atomic layer deposition (ALD) process. The silicon-and-oxygen-containing ALD may include: depositing a silicon-containing material on the substrate, purging the processing region, exposing the silicon-containing material to an oxygen-containing precursor to convert the silicon-containing material to a silicon-and-oxygen-containing material, and purging the processing region.

In some embodiments, the carbon-containing precursor may be or include acetylene (C₂H₂). The methods may include repeating providing the carbon-containing precursor and the nitrogen-containing precursor to the processing region, forming plasma effluents of the carbon-containing precursor and the nitrogen-containing precursor, contacting the substrate with the plasma effluents of the nitrogen-containing precursor and the nitrogen-containing precursor, and performing a silicon-containing ALD for a plurality of cycles to iteratively fill the one or more features. Subsequent to one or more cycles, a flow rate ratio of the carbon-containing precursor relative to the nitrogen-containing precursor may be reduced.

Such technology may provide numerous benefits over conventional systems and techniques. For example, embodiments of the present technology may control deposition of material for gap fill applications. Through intermittent inhibition during the deposition, the present technology may deposit material in features in a bottom-up, zipper-like fashion with reduced and/or prevented formation of seams and/or voids. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a schematic cross-sectional view of an exemplary plasma system according to some embodiments of the present technology.

FIG. 2 shows operations in a semiconductor processing method according to some embodiments of the present technology.

FIGS. 3A-3E show exemplary schematic cross-sectional structures in which material layers are included and produced according to some embodiments of the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

As device sizes continue to shrink, many material layers may be reduced in thickness and size to scale devices. Features inside semiconductor structures may be reduced in size, and aspect ratios of the features may increase. As the aspect ratios of the features increase, atomic layer deposition (ALD) or plasma-enhanced ALD (PEALD) may produce seams or voids within the feature.

Conventional technologies have struggled to produce films to fill high aspect ratio features in the underlying structures where seam or void formation is controlled. Deposition of silicon-containing materials on the underlying structures containing the high aspect ratio trenches may be incomplete. The conformal fill operation may allow the feature to seal near the top of the feature prior to fill within the feature, as well as to produce a seam up the middle of the feature, which can extend to the top of the structure. In some production, where a polishing operation may subsequently occur, the removal may cause the seam to be exposed, which may provide access within the feature. This may allow oxidation of the material once exposed to atmosphere, as well as incorporation of slurry or other materials along the seam. Accordingly, many conventional technologies have been limited in the ability to prevent structural flaws in the final devices. Some conventional technologies have utilized poisoning operations, such as with nitrogen-containing precursors, to maintain an opening of the gap fill material at an upper portion of the features. Other conventional technologies have utilized an intermittent etch operations, such as with a halogen-containing precursor, to maintain an opening of the gap fill material at an upper portion of the features. However, these poisoning operations and intermittent etch operations typically damage underlying material or the gap fill material to some degree, as well as potentially incorporating undesirable material into final structures.

The present technology overcomes these issues by intermittently performing an inhibition operation. The inhibition operation may form an inhibition material, such as a carbon-containing material, at upper portions of the features being filled, thereby reducing an amount of deposition of gap fill material upper portions of features being gap filled. During deposition of the gap fill material, the inhibition material may be volatilized and released from the structure. The inhibition operation and bulk gap fill may be cycled for fill the features with seam-free and/or void-free material. As the inhibition operation and bulk gap fill are cycled, one or more process conditions may be adjusted to control the amount of inhibition material being formed.

After describing general aspects of a chamber according to some embodiments of the present technology in which gap filling operations discussed below may be performed, specific methodology may be discussed. It is to be understood that the present technology is not intended to be limited to the specific films, chambers or processes discussed, as the techniques described may be used to improve a number of film formation processes, and may be applicable to a variety of processing chambers and operations.

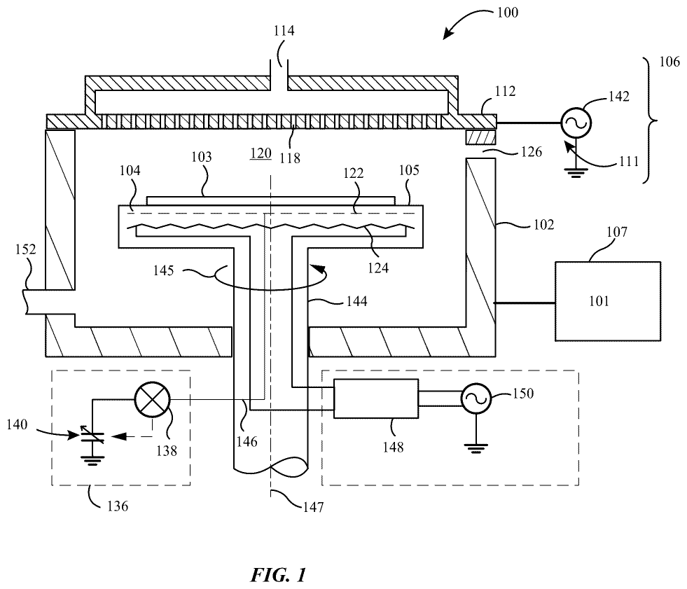

FIG. 1 shows a cross-sectional view of an exemplary processing chamber 100 according to some embodiments of the present technology. The figure may illustrate an overview of a system incorporating one or more aspects of the present technology, and/or which may be specifically configured to perform one or more operations according to embodiments of the present technology. Additional details of chamber 100 or methods performed may be described further below. Chamber 100 may be utilized to form film layers, etch material layers, form other material layers, or a combination thereof, although it is to be understood that deposition and etch methods may similarly be performed in any chamber within which deposition and etch processes may occur. The processing chamber 100 may include a chamber body 102, a substrate support 104 disposed inside the chamber body 102, and a lid assembly 106 coupled with the chamber body 102 and enclosing the substrate support 104 in a processing volume 120. A substrate 103 may be provided to the processing volume 120 through an opening 126, which may be conventionally sealed for processing using a slit valve or door. The substrate 103 may be seated on a surface 105 of the substrate support during processing. In some embodiments, the substrate support 104 may be rotatable, as indicated by the arrow 145, along an axis 147, where a shaft 14a4 of the substrate support 104 may be locate, or may be stationary. Alternatively, the substrate support 104 may be lifted up to rotate as necessary during a deposition process.

A gas distributor 112 may define apertures 118 for distributing process precursors into the processing volume 120. The gas distributor 112 may be coupled with a first source of electric power 142, such as an RF generator, RF power source, DC power source, pulsed DC power source, pulsed RF power source, or any other power source that may be coupled with the processing chamber. In some embodiments, the first source of electric power 142 may be an RF power source.

The gas distributor 112 may be a conductive gas distributor or a non-conductive gas distributor. The gas distributor 112 may also be formed of conductive and non-conductive components. For example, a body of the gas distributor 112 may be conductive while a face plate of the gas distributor 112 may be non-conductive. The gas distributor 112 may be powered, such as by the first source of electric power 142 as shown in FIG. 1, or the gas distributor 112 may be coupled with ground in some embodiments.

A first electrode 122 may be coupled with the substrate support 104. The first electrode 122 may be embedded within the substrate support 104 or coupled with a surface of the substrate support 104. The first electrode 122 may be a plate, a perforated plate, a mesh, a wire screen, or any other distributed arrangement of conductive elements. The first electrode 122 may be a tuning electrode and may be coupled with a tuning circuit 136 by a conduit 146, for example a cable having a selected resistance, such as 50 ohms, for example, disposed in the shaft 144 of the substrate support 104. The tuning circuit 136 may have an electronic sensor 138 and an electronic controller 140, which may be a variable capacitor. The electronic sensor 138 may be a voltage or current sensor and may be coupled with the second electronic controller 140 to provide further control over plasma conditions in the processing volume 120.

A second electrode 124, which may be a bias electrode and/or an electrostatic chucking electrode, may be coupled with the substrate support 104. The second electrode may be coupled with a second source of electric power 150 through a filter 148, which may be an impedance matching circuit. The second source of electric power 150 may be DC power, pulsed DC power, RF bias power, a pulsed RF source or bias power, or a combination of these or other power sources. In some embodiments, the second source of electric power 150 may be an RF bias power. The substrate support 104 may also include one or more heating elements configured to heat the substrate to a processing temperature, which may be between about 25° C. and about 800° C. or greater.

The lid assembly 106 and substrate support 104 of FIG. 1 may be used with any processing chamber for plasma or thermal processing. In operation, the processing chamber 100 may afford real-time control of plasma conditions in the processing volume 120, such as via a system controller 101 which may be contained within a processor 107. The substrate 103 may be disposed on the substrate support 104, and process gases may be flowed through the lid assembly 106 using an inlet 114 according to any desired flow plan. Gases may exit the processing chamber 100 through an outlet 152. Electric power may be coupled with the gas distributor 112 to establish a plasma in the processing volume 120. The substrate may be subjected to an electrical bias using the second electrode 124 in some embodiments.

Upon energizing a plasma in the processing volume 120, a potential difference may be established between the plasma and the first electrode 122. The electronic controller 140 may then be used to adjust the flow properties of the ground paths represented by the tuning circuit 136. A set point may be delivered to the first circuit 136 to provide independent control of deposition rate and of plasma density uniformity from center to edge. In embodiments where the electronic controllers may both be variable capacitors, the electronic sensors may adjust the variable capacitors to maximize deposition rate and minimize thickness non-uniformity independently.

Tuning circuit 136 may have a variable impedance that may be adjusted using the electronic controller 140. Where the electronic controller 140 is a variable capacitor, the capacitance range of each of the variable capacitors, may be chosen to provide an impedance range. This range may depend on the frequency and voltage characteristics of the plasma, which may have a minimum in the capacitance range of each variable capacitor. Hence, when the capacitance of the electronic controller 140 is at a minimum or maximum, impedance of the tuning circuit 136 may be high, resulting in a plasma shape that has a minimum aerial or lateral coverage over the substrate support. When the capacitance of the electronic controller 140 approaches a value that minimizes the impedance of the tuning circuit 136, the aerial coverage of the plasma may grow to a maximum, effectively covering the entire working area of the substrate support 104. As the capacitance of the electronic controller 140 deviates from the minimum impedance setting, the plasma shape may shrink from the chamber walls and aerial coverage of the substrate support may decline.

The electronic sensor 138 may be used to tune the circuit 136 in a closed loop. A set point for current or voltage, depending on the type of sensor used, may be installed in each sensor, and the sensor may be provided with control software that determines an adjustment to the respective electronic controller 140 to minimize deviation from the set point. Consequently, a plasma shape may be selected and dynamically controlled during processing. It is to be understood that, while the foregoing discussion is based on electronic controller 140, which may be a variable capacitor, any electronic component with adjustable characteristic may be used to provide tuning circuit 136 with adjustable impedance.

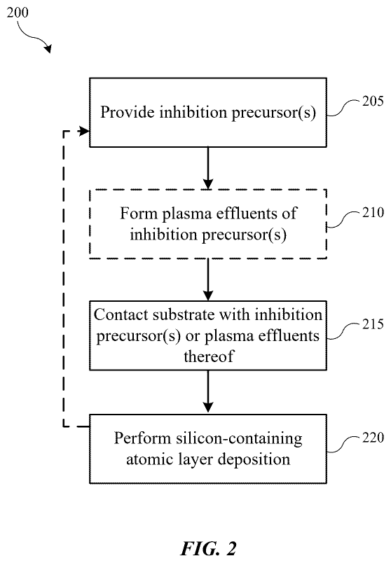

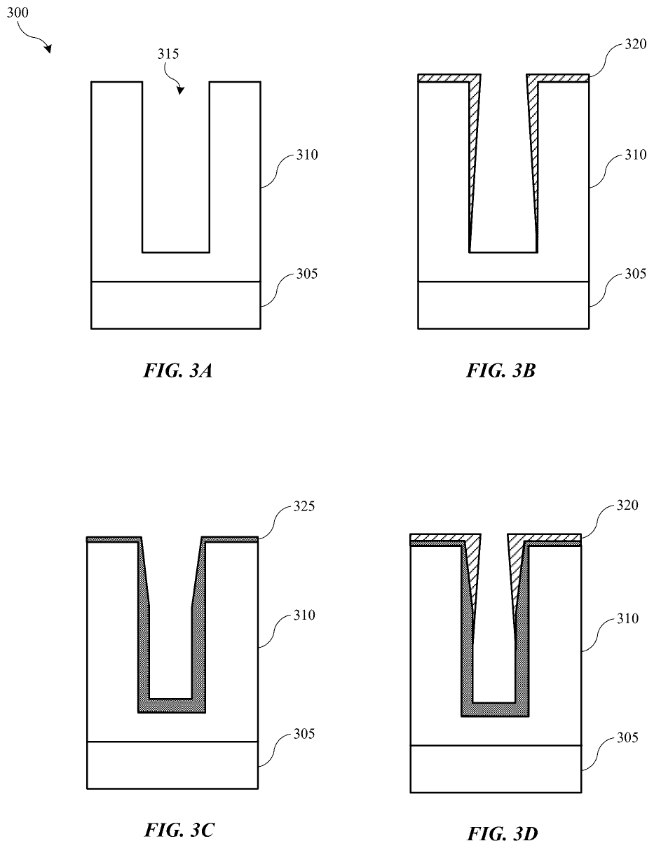

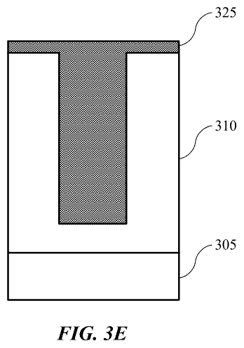

Processing chamber 100 may be utilized in some embodiments of the present technology for processing methods that may include gap filling materials for semiconductor structures intermittent inhibition to maintain a seam-free and/or void-free gap fill. It is to be understood that the chamber described is not to be considered limiting, and any chamber that may be configured to perform operations as described may be similarly used. FIG. 2 shows exemplary operations in a processing method 200 according to some embodiments of the present technology. The method may be performed in a variety of processing chambers and on one or more mainframes or tools, including processing chamber 100 described above. Method 200 may include a number of optional operations, which may or may not be specifically associated with some embodiments of methods according to the present technology. For example, many of the operations are described in order to provide a broader scope of the structural formation, but are not critical to the technology, or may be performed by alternative methodology as would be readily appreciated. Method 200 may describe operations shown schematically in FIGS. 3A-3E, the illustrations of which will be described in conjunction with the operations of method 200. It is to be understood that the figures illustrate only partial schematic views, and a substrate may contain any number of additional materials and features having a variety of characteristics and aspects as illustrated in the figures.

Method 200 may include additional operations prior to initiation of the listed operations. For example, additional processing operations may include forming structures on a substrate, which may include both forming and removing material. For example, transistor structures, memory structures, or any other structures may be formed. Prior processing operations may be performed in the chamber in which method 200 may be performed, or processing may be performed in one or more other processing chambers prior to delivering the substrate into the semiconductor processing chamber or chambers in which method 200 may be performed. Regardless, method 200 may optionally include delivering a semiconductor substrate to a processing region of a semiconductor processing chamber, such as processing chamber 100 described above, or other chambers that may include components as described above. The substrate may be deposited on a substrate support, which may be a pedestal such as substrate support 104, and which may reside in a processing region of the chamber, such as processing volume 120 described above.

As illustrated in FIG. 3A, a substrate on which several operations have been performed may be substrate 305 of a structure 300, which may show a partial view of a substrate on which semiconductor processing may be performed. It is to be understood that structure 300 may show only a few top layers during processing to illustrate aspects of the present technology. The substrate 305 may include a layer of material 310 in which one or more features 315 may be formed. Substrate 305 may be any number of materials used in semiconductor processing. The substrate 305 material may be or include silicon, germanium, dielectric materials including silicon oxide or silicon nitride, metal materials, or any number of combinations of these materials, which may be the substrate 305, or materials formed in structure 300. Features 315 may be characterized by any shape or configuration according to the present technology. In some embodiments, the features 315 may be or include a trench structure or aperture formed within the substrate 305 or layer of material 310.

Although the features 315 may be characterized by any shapes or sizes, in some embodiments, the features 315 may be characterized by higher aspect ratios, or a ratio of a depth of the feature to a width across the feature. For example, in some embodiments, features 315 may be characterized by aspect ratios greater than or about 10:1, and may be characterized by aspect ratios greater than or about 25:1, greater than or about 30:1, greater than or about 35:1, greater than or about 40:1, greater than or about 45:1, greater than or about 50:1, greater than or about 60:1, greater than or about 70:1, greater than or about 80:1, greater than or about 90:1, greater than or about 100:1, greater than or about 110:1, greater than or about 120:1, greater than or about 130:1, greater than or about 140:1, greater than or about 150:1, greater than or about 175:1, greater than or about 200:1, or greater. Additionally, while features 315 are illustrated as with a consistent diameter along the length of the features 315, it is contemplated the features 315 may have different geometries or tapering.

Additionally, the features 315 may be characterized by narrow widths or diameters across the feature including between two sidewalls, such as a dimension less than or about 250 nm, and may be characterized by a width across the feature of less than or about 200 nm, less than or about 150 nm, less than or about 100 nm, less than or about 90 nm, less than or about 80 nm, less than or about 70 nm, less than or about 60 nm, less than or about 50 nm, less than or about 40 nm, less than or about 30 nm, or less. Further, the features may be characterized by a depth of greater than or about 100 nm, and may be characterized by a depth of greater than or about 250 nm, greater than or about 500 nm, greater than or about 750 nm, greater than or about 1 μm, greater than or about 1.5 μm, greater than or about 2 μm, greater than or about 2.5 μm, greater than or about 3 μm, greater than or about 3.5 μm, greater than or about 4 μm, greater than or about 4.5 μm, greater than or about 5 μm, greater than or about 5.5 μm, or more.

Method 200 may include forming gap fill materials for semiconductor structures. However, to reduce or eliminate the presence of a seam or a void in the gap fill material within the feature, which may occur in conventional atomic layer deposition (ALD) or plasma-enhanced ALD (PEALD) processes, method 200 may include inhibition operations. As such, method 200 may include performing an inhibition operation prior to performing the gap filling. The inhibition operation of method 200 may include providing one or more inhibition precursors, such as a carbon-containing precursor or other inhibition precursor, to the processing region of the semiconductor processing chamber at operation 205. In embodiments, method 200 may include providing a nitrogen-containing precursor to the processing region with the oxygen-containing precursor at operation 205. At optional operation 210, the inhibition operation of method 200 may include forming plasma effluents of the carbon-containing precursor. At operation 215, the inhibition operation of method 200 may include contacting the substrate 305 with the carbon-containing precursor or plasma effluents thereof. As illustrated in FIG. 3B, the contacting may form an inhibition material 320, which may be a carbon-containing material, on an upper portion of the one or more features 315.

Although any carbon-containing precursor may be used during the inhibition, in some embodiments, the carbon-containing precursor may be a hydrocarbon. For example, the carbon-containing precursor may be or include, but is not limited to, methane (CH₄), ethylene (C₂H₄), acetylene (C₂H₂), and propane (C₃H₈), or any other carbon-containing precursor that may be used or useful in semiconductor processing. Additionally, although any nitrogen-containing precursor may be used during the inhibition, in some embodiments, the nitrogen-containing precursor may be or include diatomic nitrogen (N₂), ammonia (NH₃), diimide (N₂H₂), hydrazine (N₂H₄), or any other nitrogen-containing precursor that may be used or useful in semiconductor processing. The carbon-containing precursor and, if present, the nitrogen-containing precursor may be provided with one or more diluents or carrier gases such as an inert gas or other gas delivered with the carbon-containing precursor. For example, the carbon-containing precursor and, if present, the nitrogen-containing precursor may be provided with argon (Ar), helium (He), xenon (Xe), or any other non-reactive material. The inert gas or other gas may be provided for dilution and/or distribution of the carbon-containing precursor and, if present, the nitrogen-containing precursor.

In embodiments, a flow rate of the carbon-containing precursor may be selected to provide a desired amount of inhibition material 312. More specifically, at higher flow rates of the carbon-containing precursor, a greater amount of inhibition material 320 may be formed. In embodiments, the flow rate of the carbon-containing precursor, may be greater than or about 100 sccm, and may be greater than or about 250 sccm, greater than or about 500 sccm, greater than or about 750 sccm, greater than or about 1,000 sccm, greater than or about 1,500 sccm, greater than or about 2,000 sccm, greater than or about 3,000 sccm, greater than or about 4,000 sccm, or more. However, to balance the amount of inhibition material 320, such that the subsequent deposition may not be hindered by the inhibition material 320, the flow rate of the carbon-containing precursor, may be less than or about 3,000 sccm, and may be less than or about 2,500 sccm, less than or about 2,000 sccm, less than or about 1,500 sccm, less than or about 1,000 sccm, less than or about 750 sccm, less than or about 500 sccm, less than or about 250 sccm, less than or about 100 sccm, or less.

A flow rate of the nitrogen-containing precursor, if present, may be selected to provide a desired amount of inhibition material 320. The nitrogen-containing precursor may reduce a thickness of the inhibition material 320, as the nitrogen-containing precursor, or plasma effluents thereof, may react with the inhibition material 320, which may be carbon-containing material, and result in etching of the inhibition material 320. In embodiments, to adequately maintain an opening of the features 315 by etching the inhibition material 320, the flow rate of the nitrogen-containing precursor, may be greater than or about 100 sccm, and may be greater than or about 250 sccm, greater than or about 500 sccm, greater than or about 750 sccm, greater than or about 1,000 sccm, greater than or about 1,500 sccm, greater than or about 2,000 sccm, greater than or about 3,000 sccm, greater than or about 4,000 sccm, or more. However, to balance the amount of inhibition material 320, such that subsequent gap fill is sufficiently reduced by the inhibition material 320, the flow rate of the nitrogen-containing precursor, may be less than or about 4,000 sccm, and may be less than or about 3,000 sccm, less than or about 2,000 sccm, less than or about 1,500 sccm, less than or about 1,000 sccm, less than or about 750 sccm, less than or about 500 sccm, less than or about 250 sccm, less than or about 100 sccm, or less.

A flow rate ratio of the carbon-containing precursor relative to the nitrogen-containing precursor may be selected to balance formation of the inhibition material 320 versus etching of the inhibition material 320. Increased flow rate ratios of the carbon-containing precursor relative to the nitrogen-containing precursor may result in increased tapering of the inhibition material 320. Increased flow rate ratios of the carbon-containing precursor relative to the nitrogen-containing precursor may result in less etching of the inhibition material 320, which may result in the inhibition material 320 extending further into the features 315 and with an increased taper. Increased taper may refer to a quicker decrease in thickness from an upper portion of the features 315 toward a bottom portion of the inhibition material 320. As such, the flow rate ratio of the carbon-containing precursor relative to the nitrogen-containing precursor may be greater than or about 1:2, and may be greater than or about 1:1, greater than or about 2:1, greater than or about 3:1, greater than or about 4:1, greater than or about 5:1, or more. Conversely, to reduce tapering of the inhibition material 320 and reduce the depth of the inhibition material 320 in the features 315, the flow rate ratio of the carbon-containing precursor relative to the nitrogen-containing precursor may be reduced. Similarly, reduced taper may refer to a slower decrease in thickness from an upper portion of the features 315 toward a bottom portion of the inhibition material 320. Reduced taper of the inhibition material 320 may result in a more uniform thickness of the inhibition material 320, or less of a change in thickness, in the direction of the features 315 compared to increased taper of the inhibition material 320. For example, the flow rate ratio of the carbon-containing precursor relative to the nitrogen-containing precursor may be less than or about 5:1, and may be less than or about 4:1, less than or about 3:1, less than or about 2:1, less than or about 1:1, less than or about 1:2, or less.

Some embodiments may include forming plasma effluents of the carbon-containing precursor, or other inhibition precursor, and/or nitrogen-containing precursor at optional operation 210. The plasma power applied during at optional operation 210 may be a lower power plasma, which may reduce dissociation and control the amount of inhibition material 320 being formed. Accordingly, in some embodiments a plasma power source may deliver a plasma power to the faceplate, chamber, or substrate support of less than or about 2,500 W, and may deliver a power of less than or about 2,000 W, less than or about 1,500 W, less than or about 1,000 W, less than or about 750 W, less than or about 500 W, less than or about 450 W, less than or about 400 W, less than or about 350 W, less than or about 300 W, less than or about 250 W, less than or about 200 W, less than or about 150 W, less than or about 100 W, or less.

As previously discussed, contacting the substrate 305 with the carbon-containing precursor and, if present, the nitrogen-containing precursor, or plasma effluents thereof may form inhibition material 320, which may be a carbon-containing material, on an upper portion of the one or more features 315. Unlike some conventional inhibition operations, which may physisorb or chemisorb inhibition material on a surface of the underlying material, the present technology may actually form an inhibition material 320. Conventional inhibition operations using ion-based adsorption may damage the underlying material, such as the layer of material 310. Conversely, the present technology, in forming an actual layer of inhibition material 320, may not result in damage of the layer of material 310. The inhibition material 320 may extend along an upper portion of the features 315 and may not conformally line the features 315. While a depth of inhibition material 320 may depend on a variety of process factors and the dimensions of the features 315, embodiments of the present technology may form inhibition material 320 that may extend greater than or about 100 nm into the features 315, and may extend greater than or about 250 nm, greater than or about 500 nm, greater than or about 750 nm, greater than or about 1 μm, greater than or about 1.25 μm, greater than or about 1.5 μm, greater than or about 1.75 μm, greater than or about 2 μm, greater than or about 2.25 μm, greater than or about 2.5 μm, greater than or about 2.75 μm, greater than or about 3 μm, greater than or about 3.25 μm, greater than or about 3.5 μm, greater than or about 3.75 μm, greater than or about 4 μm, greater than or about 4.25 μm, greater than or about 4.5 μm, greater than or about 4.75 μm, greater than or about 5 μm, or more, which may depend on the depth of the features 315.

As further discussed below, in subsequent cycles of method 200, one or more processing conditions may be adjusted to control an amount of inhibition material 320 and/or the depth of the upper portion of the features 315 that the inhibition material 320 forms on. For example, in subsequent cycles of method 200, one or more of the flow rate of the carbon-containing precursor, the flow rate ratio of the carbon-containing precursor relative to the nitrogen-containing precursor, the plasma power, exposure time to the inhibition precursors, the temperature, and/or the pressure may be adjusted to control an amount of inhibition material 320 and/or the depth of the upper portion of the features 315 that the inhibition material 320 forms on.

Subsequent to performing the inhibition operation at operations 205-215, method 200 may include performing a silicon-containing ALD at operation 220. As illustrated in FIG. 3C, the silicon-containing ALD may deposit a silicon-containing material 325, such as silicon-and-oxygen-containing material, in the one or more features 315. The deposition may be performed in the same chamber as the inhibition, and may be performed in a cyclic process to fill the feature 315.

The silicon-containing ALD or PEALD may include a layer-by-layer deposition of silicon-containing material 325, which may be a silicon-and-oxygen-containing material. The silicon-containing ALD or PEALD may include a first precursor dose, such as a silicon-containing precursor dose or an oxygen-containing precursor dose. In silicon-containing PEALD, plasma effluents of the first precursor dose may be formed. The first precursor dose or, if formed, plasma effluents thereof may be adsorbed, such as through chemisorption, on the substrate 305 or layer of material 310. In embodiments, the first precursor dose may deposit a silicon-containing material on the substrate 305. A first purge may be performed to remove excess amounts of the first precursor dose, such as the first precursor that has not been absorbed on the substrate 305 or layer of material 310.

After the first purge, the silicon-containing ALD or PEALD may include a second precursor dose, such as a silicon-containing precursor dose or an oxygen-containing precursor (the opposite of the first precursor dose). In silicon-containing PEALD, plasma effluents of the second precursor dose may be formed. The second precursor or, if formed, plasma effluents thereof may react with the first precursor dose adsorbed on the substrate 305 or layer of material 310. The reaction between the first precursor dose and the second precursor dose may form the silicon-containing material 325. In embodiments, the second precursor dose may expose the silicon-containing material to an oxygen-containing precursor to convert the silicon-containing material to a silicon-and-oxygen-containing material. In other embodiments, the second precursor dose may be another material to form a different silicon-containing material. For example, the second precursor dose may utilize a carbon-containing precursor or a nitrogen-containing precursor to form a silicon-and-carbon-containing material or a silicon-and-nitrogen-containing material, respectively. A second purge may be performed to remove excess amounts of the second precursor dose, such as the second precursor that has not reacted with the first precursor to form silicon-containing material 325.

As illustrated in FIG. 3C, the inhibition operation, which may form inhibition material 320, may reduce deposition of silicon-containing material 325 at an upper portion of the one or more features 315. Deposition of silicon-containing material 325 at upper portions of the one or more features 315 may not be prevented entirely, as precursors for the ALD or PEALD may diffuse through the inhibition material 320. Additionally, when exposed to oxygen-containing precursor(s) during the silicon-containing ALD or PEALD, the inhibition material 320 may be at least partially removed. The inhibition material 320, which may be a carbon-containing material, may be volatilized and outgassed as carbon monoxide (CO), carbon dioxide (CO₂), dicarbon monoxide (C₂O), or any other carbon-and-containing material. This may limit an impact of the inhibition material 320 in final structures. Nevertheless, the inhibition operation to form inhibition material 320 may prevent closing of or pinching off of the one or more features 315 with silicon-containing material 325.

Although any silicon-containing precursor may be used, in some embodiments, the silicon-containing precursor(s) may be used during the silicon-containing ALD or PEALD may include, but are not limited to, silane (SiH₄), disilane (Si₂H₆), trisilane (Si₃H₈), tetrasilane (Si₄H₁₀), pentasilane (Si₅H₁₂), or other organosilanes including cyclohexasilanes, an aminosilane, silicon tetrafluoride (SiF₄), silicon tetrachloride (SiCl₄), dichlorosilane (SiH₂Cl₂), tetraethyl orthosilicate (TEOS), as well as any other silicon-containing materials that may be used or useful in semiconductor processing. Similarly, although any oxygen-containing precursor may be used, in some embodiments, the oxygen-containing precursor(s) may be used during the silicon-containing ALD or PEALD may include, but are not limited to, diatomic oxygen (O₂), nitrous oxide (N₂O), hydrogen peroxide (H₂O₂), or other oxygen-containing materials that may be used or useful in semiconductor processing.

If plasma-enhanced, a plasma power source may deliver a plasma power to the faceplate, chamber, or substrate support of greater than or about 250 W, and may deliver a power of greater than or about 500 W, greater than or about 1,000 W, greater than or about 1,500 W, greater than or about 2,000 W, greater than or about 2,500 W, greater than or about 3,000 W, greater than or about 3,500 W, greater than or about 4,000 W, greater than or about 4,500 W, greater than or about 5,000 W, greater than or about 5,500 W, greater than or about 6,000 W, greater than or about 7,000 W, greater than or about 8,000 W, or more.

After the second purge, the first precursor dose, first purge, and second precursor dose, and second purge may be repeated any number of times to continue forming silicon-containing material 325. The deposition may be conformal, and thus, growth may occur inward within the feature 315 from the walls defining the features 315. The silicon-containing ALD or PEALD may be performed for a period of time sufficient to produce an amount of coverage to at least partially fill the features 315. Without intermittent inhibition at operations 205-215, as the features 315 closes, a seam and/or a void may be formed. The seam and/or void may extend a portion or all of a distance of the features 315 to an exposed upper surface. The seam and/or void may be characterized by a number of shapes, which may include top-wide, bottom wide, as well as a more amorphous shape, as would be readily understood by the skilled artisan. To reduce or prevent the formation of the seam and/or void, method 200 may include intermittently performing the inhibition at operations 205-215 during the bulk deposition of silicon-containing material 325 at the silicon-containing ALD or PEALD at operation 220 for a plurality of cycles.

Temperature may impact operations of the present technology. For example, the method 200 may be performed at a temperature less than or about 600° C., and may be performed at a temperature less than or about less than or about 575° C., less than or about 550° C., less than or about 525° C., less than or about 500° C., less than or about 475° C., less than or about 450° C., less than or about 425° C., less than or about 400° C., less than or about 375° C., less than or about 350° C., less than or about 325° C., less than or about 300° C., or less. Additionally, the method 200 may be performed at a temperature greater than or about 100° C., and may be performed at a temperature greater than or about 300° C., and may be performed at a temperature greater than or about 325° C., greater than or about 350° C., greater than or about 375° C., greater than or about 400° C., greater than or about 425° C., greater than or about 450° C., greater than or about 475° C., greater than or about 500° C., greater than or about 525° C., greater than or about 550° C., greater than or about 575° C., greater than or about 600° C., or more. The temperature may be maintained in any of these ranges throughout method 200. To limit temperature adjustments in the semiconductor processing chamber, the inhibition may be performed at the same temperature or at a similar temperature to the silicon-containing ALD or PEALD. However, it is also contemplated that temperature may be adjusted during operations of method 200.

Pressure may also impact operations of the present technology. For example, the method 200 may be performed at a pressure less than or about 50 Torr, and may be performed at a pressure less than or about 40 Torr, less than or about 30 Torr, less than or about 28 Torr, less than or about 28 Torr, less than or about 26 Torr, less than or about 25 Torr, less than or about 24 Torr, less than or about 22 Torr, less than or about 20 Torr, less than or about 18 Torr, less than or about 16 Torr, less than or about 15 Torr, or less. Similar to temperature, to limit pressure adjustments in the semiconductor processing chamber, the inhibition may also be performed at the same pressure or at a similar pressure to the silicon-containing ALD or PEALD. However, it is also contemplated that pressure may be adjusted during operations of method 200.

Some or all of the operations of method 200 may be repeated for a plurality of cycles. As illustrated in FIGS. 3D-3E, which may span numerous cycles of method 200, the repetition may fill the features 315 with silicon-containing material 325 in a bottom-up and/or zipper-like fashion. By filling the features 315 in bottom-up and/or zipper-like fashion, the formation of seams and/or voids may be reduced or prevented entirely.

As previously discussed, subsequent to one or more cycles of method 200, one or more processing conditions may be adjusted to control an amount of inhibition material 320 and/or the depth of the upper portion of the features 315 that the inhibition material 320 forms on. For example, in subsequent cycles of method 200, the pressure within the processing region may be reduced. At reduced pressures, deposition rate may decrease. Reduced pressures may result in less radicals of the carbon-containing precursor, which may result in a slower reduced rate. Additionally, reduced pressures may reduce a distance at which the carbon-containing precursor or plasma effluents thereof are able to penetrate in the features 315, resulting in the inhibition material 320 forming less deep into the features 315. As another example, the plasma power, such as a source power, may be decreased in subsequent cycles of method 200. At reduced plasma powers, less radicals of the carbon-containing precursor may be formed. With less radicals, the carbon-containing radicals may form inhibition material 320 earlier on sidewalls of the features 315, resulting in the inhibition material 320 not extending as far into the features 315. As yet another example, the flow rate ratio of the carbon-containing precursor relative to the nitrogen-containing precursor may be decreased in subsequent cycles of method 200. With an increased amount of the nitrogen-containing precursor, an increased amount of the inhibition material 320 may result. This may reduce the amount of inhibition material 320 formed and may reduce the depth at which the inhibition material 320 extends. The reduced inhibition material 320 and reduced depth of the inhibition material 320 may allow the silicon-containing material 325 to grow conformally from the sidewalls of the features 315 at a reduced depth. While pressure, plasma power, and flow rate ratio are three examples, it is contemplated that other processing conditions may be adjusted together or individually to tun the profile of the inhibition material 320.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a carbon-containing precursor” includes a plurality of such precursors, and reference to “the silicon-containing material” includes reference to one or more materials and equivalents thereof known to those skilled in the art, and so forth. “About” and/or “approximately” as used herein when referring to a measurable value such as an amount, a temporal duration, and the like, encompasses variations of ±20% or ±10%, ±5%, or +0.1% from the specified value, as such variations are appropriate to in the context of the systems, devices, circuits, methods, and other implementations described herein. “Substantially” as used herein when referring to a measurable value such as an amount, a temporal duration, a physical attribute (such as frequency), and the like, also encompasses variations of ±20% or ±10%, ±5%, or +0.1% from the specified value, as such variations are appropriate to in the context of the systems, devices, circuits, methods, and other implementations described herein.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A semiconductor processing method comprising:
i) performing a carbon inhibition operation on a substrate disposed within a processing region of a semiconductor processing chamber, wherein a layer of material is disposed on the substrate, and wherein the layer of material defines one or more features characterized by an aspect ratio of greater than or about 30:1;
ii) performing a silicon-containing atomic layer deposition (ALD) process, wherein the silicon-containing ALD deposits a silicon-containing material in the one or more features; and
iii) repeating operations i and ii for a plurality of cycles.

2. The semiconductor processing method of claim 1, wherein the one or more features are characterized by a width of less than or about 250 nm.

3. The semiconductor processing method of claim 1, wherein the one or more features are characterized by a depth of greater than or about 1 μm.

4. The semiconductor processing method of claim 1, wherein the one or more features are characterized by an aspect ratio of greater than or about 50:1.

5. The semiconductor processing method of claim 1, wherein the inhibition operation comprises contacting the substrate with a carbon-containing precursor.

6. The semiconductor processing method of claim 5, wherein the carbon-containing precursor comprises acetylene (C₂H₂).

7. The semiconductor processing method of claim 5, further comprising:
forming plasma effluents of the carbon-containing precursor.

8. The semiconductor processing method of claim 1, wherein the inhibition operation reduces deposition of silicon-containing material at an upper portion of the one or more features.

9. The semiconductor processing method of claim 1, wherein the silicon-containing ALD comprises:
ii-a) depositing the silicon-containing material on the substrate;
ii-b) purging the processing region after operation ii-a;
ii-c) exposing the silicon-containing material to an oxygen-containing precursor to convert the silicon-containing material to a silicon-and-oxygen-containing material; and
ii-d) purging the processing region after operation ii-c.

10. The semiconductor processing method of claim 1, wherein the silicon-containing ALD is plasma-enhanced.

11. The semiconductor processing method of claim 1, wherein the inhibition operation prevents closing of the one or more features with the silicon-containing material.

12. The semiconductor processing method of claim 1, wherein the silicon-containing material is seam-free and void-free.

13. The semiconductor processing method of claim 1, wherein, subsequent to one or more cycles, a pressure within the processing region is reduced.

14. A semiconductor processing method comprising:
providing a carbon-containing precursor to a processing region of a semiconductor processing chamber, wherein a substrate is housed within the processing region, wherein a layer of material is disposed on the substrate, and wherein the layer of material defines one or more features characterized by an aspect ratio of greater than or about 30:1;
forming plasma effluents of the carbon-containing precursor;
contacting the substrate with the carbon-containing precursor, wherein the contacting forms a carbon-containing material on an upper portion of the one or more features; and
performing a silicon-and-oxygen-containing atomic layer deposition (ALD) process, wherein the silicon-and-oxygen-containing ALD deposits a silicon-and-oxygen-containing material in the one or more features.

15. The semiconductor processing method of claim 14, wherein the carbon-containing precursor comprises acetylene (C₂H₂).

16. The semiconductor processing method of claim 14, further comprising:
repeating providing the carbon-containing precursor to the processing region, contacting the substrate with the carbon-containing precursor, and performing a silicon-containing ALD for a plurality of cycles to iteratively fill the one or more features.

17. The semiconductor processing method of claim 16, wherein, subsequent to one or more cycles, a plasma power is reduced.

18. A semiconductor processing method comprising:
providing a carbon-containing precursor and a nitrogen-containing precursor to a processing region of a semiconductor processing chamber, wherein a substrate is housed within the processing region, wherein a layer of material is disposed on the substrate, and wherein the layer of material defines one or more features characterized by an aspect ratio of greater than or about 30:1;
forming plasma effluents of the carbon-containing precursor and the nitrogen-containing precursor;
contacting the substrate with the plasma effluents of the nitrogen-containing precursor and the nitrogen-containing precursor, wherein the contacting forms a carbon-containing material on an upper portion of the one or more features; and
performing a silicon-and-oxygen-containing atomic layer deposition (ALD) process, wherein the silicon-and-oxygen-containing ALD comprises:
depositing a silicon-containing material on the substrate;
purging the processing region;
exposing the silicon-containing material to an oxygen-containing precursor to convert the silicon-containing material to a silicon-and-oxygen-containing material; and
purging the processing region.

19. The semiconductor processing method of claim 18, wherein the carbon-containing precursor comprises acetylene (C₂H₂).

20. The semiconductor processing method of claim 18, further comprising:
repeating providing the carbon-containing precursor and the nitrogen-containing precursor to the processing region, forming plasma effluents of the carbon-containing precursor and the nitrogen-containing precursor, contacting the substrate with the plasma effluents of the nitrogen-containing precursor and the nitrogen-containing precursor, and performing a silicon-containing ALD for a plurality of cycles to iteratively fill the one or more features, wherein, subsequent to one or more cycles, a flow rate ratio of the carbon-containing precursor relative to the nitrogen-containing precursor is reduced.
